(19) United States
(12) Patent Application Publication
(10) Pub. No.: US 2014/0167842 A1
(43) Pub. Date: Jun. 19, 2014

(54) POWER CIRCUIT AND METHOD THEREOF

(71) Applicant: MediaTek Inc., Hsin-Chu (TW)

(72) Inventors: Yang-Wen CHEN, New Taipei City (TW); Chih-Sheng YANG, Zhubei City (TW)

(73) Assignee: MediaTek Inc., Hsin-Chu (TW)

(21) Appl. No.: 14/010,138

(22) Filed: Aug. 26, 2013

Related U.S. Application Data
(60) Provisional application No. 61/736,653, filed on Dec. 13, 2012.

(51) Int. Cl. H03F 3/20

(52) U.S. Cl. CPC H03F 3/20
USPC 330/127

(57) ABSTRACT

A power circuit and a method thereof are provided. The method includes: determining, by a power controller, a first signal is to be transmitted in the continuous mode or the burst mode; when the first signal is to be transmitted in the continuous mode, activating, by a power controller, a continuous mode converter; when activated, converting, by the continuous mode converter, a first voltage down to a second voltage and supplying the second voltage to the first power amplifier; when the first signal is to be transmitted in the burst mode, activating, by a power controller, a burst mode converter; when activated and the first power amplifier is inactive, receiving, by a burst mode converter, a first current to accumulate a burst energy; and when activated and the first power amplifier is active, supplying, by the burst mode converter, the burst energy to the first power amplifier.

### CROSS REFERENCE TO RELATED APPLICATIONS

This Application claims priority of U.S. Provisional Application No. 61/736,653, filed on Dec. 13, 2012, and the entirety of which is incorporated by reference herein.

### BACKGROUND OF THE INVENTION

1. Field of the Invention

The present invention relates to power management, and in particular relates to a power circuit providing power management for a power amplifier and a method thereof.

2. Description of the Related Art

Communication devices such as laptop computers or mobile phones are in use throughout everyday life. As increasing numbers of capabilities and functionalities are incorporated into the communication devices, the power requirements are ever-growing. Meanwhile, there is an on-going demand for a prolonged length of time between recharging or battery replacement. To accommodate the demands for the increased functionalities and prolonged battery life, communication devices with power management are in need.

### BRIEF SUMMARY OF THE INVENTION

A detailed description is given in the following embodiments with reference to the accompanying drawings.

An embodiment of a power circuit is described, comprising a continuous mode converter, a burst mode converter and a power controller. When activated, the continuous mode converter is configured to convert the first voltage down to a second voltage. When activated, the burst mode converter is configured to receive the first current to accumulate a burst energy when the first power amplifier is inactive, and supply the burst energy to the first power amplifier when the first power amplifier is active. The power controller, configured to determine a first signal is to be transmitted in the continuous mode or the burst mode, when the first signal is to be transmitted in the continuous mode, activate the continuous mode converter to apply the second voltage to the first power amplifier to transmit the first signal, and when the first signal is to be transmitted in the burst mode, activate the burst mode converter to provide the burst energy to the first power amplifier to transmit the first signal.

Another embodiment of a method is disclosed, adopted by a power circuit to provide powers to a first power amplifier operating in a continuous mode or in a burst mode, comprising: determining, by a power controller, a first signal is to be transmitted by the first power amplifier in the continuous mode or the burst mode; when the first signal is to be transmitted in the continuous mode, activating, by a power controller, a continuous mode converter; when activated, converting, by the continuous mode converter, a first voltage down to a second voltage; when activated, supplying, by the continuous mode converter, the second voltage to the first power amplifier; when the first signal is to be transmitted in the burst mode, activating, by a power controller, a burst mode converter; when activated and the first power amplifier is inactive, receiving, by a burst mode converter, a first current to accumulate a burst energy; and when activated and the first power amplifier is active, supplying, by the burst mode converter, the burst energy to the first power amplifier.

### BRIEF DESCRIPTION OF THE DRAWINGS

The present invention can be more fully understood by reading the subsequent detailed description and examples with references made to the accompanying drawings, wherein:

FIG. 1 is a block diagram of a communication device 1 according to an embodiment of the invention.

FIG. 2 is a block diagram of a power circuit 2 according to an embodiment of the invention;

FIG. 3 is a block diagram of a power circuit 3 according to another embodiment of the invention;

FIG. 4 is a block diagram of a power circuit 4 according to another embodiment of the invention;

FIG. 5 is a flowchart of a power control method 5 according to an embodiment of the invention;

FIG. 6 is a flowchart of a power control method 6 according to another embodiment of the invention; and

FIG. 7 is a flowchart of a power control method 7 according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

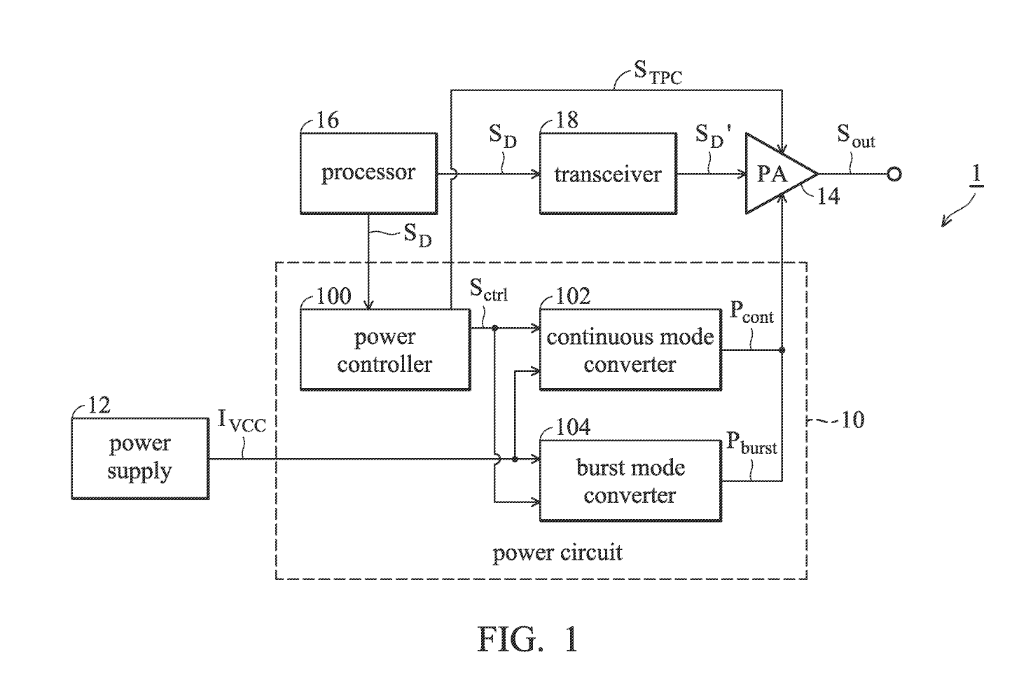

FIG. 1 is a block diagram of a communication device 1 according to an embodiment of the invention, including a power circuit 10, a power supply 12, a power amplifier (PA) 14, a processor 16 and a transceiver 18. The power supply 12 is coupled to the power circuit 10, then to the PA 14. The processor 16 is coupled to the power circuit 10 and the transceiver 18, then to the PA 16.

The communication device 1 may be a computer device such as a laptop computer and a tablet computer, a mobile communication device such as a smart phone, or any computing device capable of providing a continuous mode (CM) communication and a burst mode (BM) communication. In the CM communication, a steady, uninterrupted stream of data is transmitted in a DC balanced signal. Consequently a power amplifier (PA) for transmitting CM data requires a continuous power supply. In the BM communication, different communication devices transmit short bursts for a short period of time. For any given communication device, there is a short period of silence between two bursts. Therefore, a PA for transmitting BM data is active when the bursts occur, and is inactive during the silence. For example, a mobile phone may be required to provide wideband code division multiplex access (WCDMA) services by the CM communication and time division multiplex access (TDMA) services such as GSM services by the BM communication; a laptop computer may be require to perform CPU services by the CM communications and USB, WiFi, Bluetooth, near field communication (NFT), and other TDMA services by the BM communications.

To account for the power requirement for the different traffic behaviors between the CM and BM communications, the power circuit 10 in the embodiment is configured to identify the type of a data communication to start with, and supply the power to the PA 14 according to the type of the data communication, thereby providing required power supply for each type of the data communication, preserving communication performance while preventing from draining the limited power source such as a battery for mobile devices.

The power supply 12 may be a battery in a mobile phone or a power adaptor attached to a laptop computer, feeding a DC supply voltage VCC (first voltage) and a supply current I_{VCC} (first current) into the power circuit 10. In the case for the battery, an internal resistance of the battery will gradually increase as the battery continues discharging, leading to a reduced DC supply voltage VCC beyond a usable level, and shutting down the communication device 1 at this point.

The power circuit 10 includes a power controller 100, a continuous mode converter 102 and a burst mode converter 104, of which the later two converters respectively provide for a continuous power P_{cont} and a burst power P_{burst} to the PA 14 according to the type of data communication. The power controller 100 is configured to determine a communication type of an outgoing traffic, in order to select one from the continuous mode converter 102 and the burst mode converter 104 to supply the appropriate type of power to the PA 14. Further, the power controller 100 is configured to adjust transmit power of the PA 14 by a transmit power control signal S_{TPC}. Specifically, the power controller 100 can increase or decrease (back off) the transmit power of the PA 14 via the transmit power control signal S_{TPC} based on the supply voltage VCC, the internal resistance of the power supply 12, and the supply current drawn from the power supply 12.

The power controller 100 is configured to receive a data stream S_{D} from the processor 16 to determine the communication type belongs to the CM communication or the BM communication, or instead, receive a communication type indication signal (not shown) from the processor 16, which indicates the communication type of the data stream S_{D}. The power controller 100 is then configured to control activation and deactivation of the continuous mode converter 102 and the burst mode converter 104 according to the communication type. When the CM communication is on, the power controller 100 is configured to activate the continuous mode converter 102. When the BM communication is on, the power controller 100 is configured to activate the burst mode converter 104.

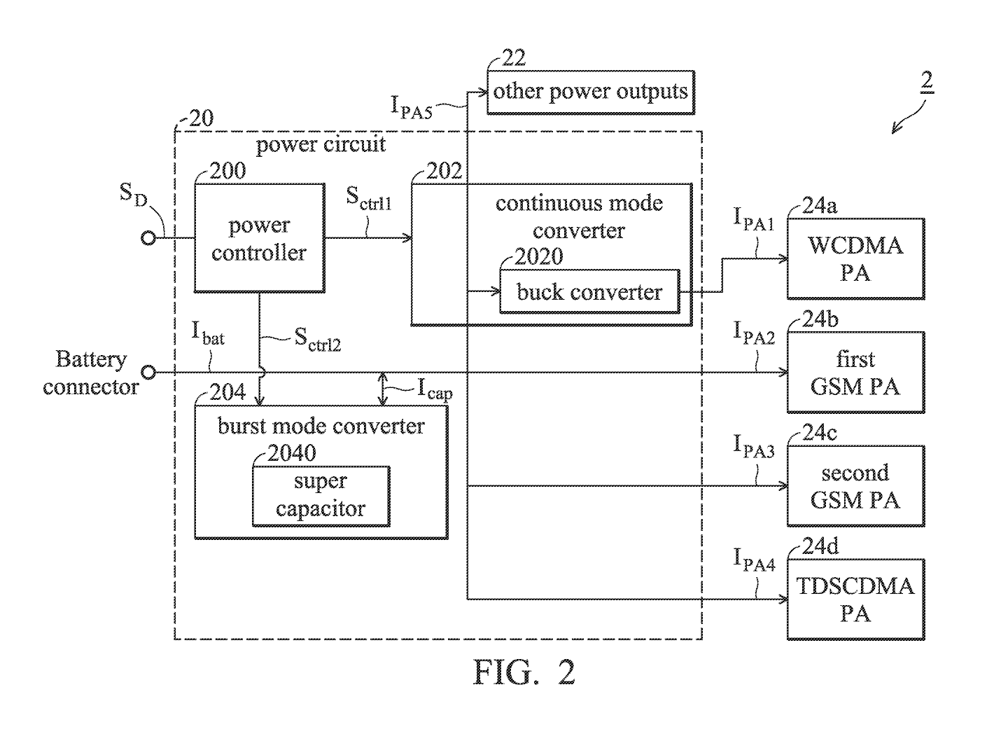

Since both converters 102 and 104 are configured to supply the power to the PA 14, only one converter can be activated at a time. When the continuous mode converter 102 is activated and the burst mode converter 104 is deactivated, the continuous mode converter 102 is configured to down-convert the supply voltage VCC to a step-down voltage (second voltage) and provide the step-down voltage and a continuous driving current to drive the PA 10, thereby supply the continuous power P_{cont} for the CM traffic. The continuous mode converter 102 can operate at a step-down voltage, with a substantially same level of the continuous driving current as the input current supplied to the PA 14, leading to the decreased the power requirement of the CM traffic and the extended battery life. The continuous mode converter 102 may be implemented by a buck converter, as depicted in FIGS. 2 through 4.

When the burst mode converter 104 is activated and the continuous mode converter 102 is deactivated, the burst mode converter 104 is configured to accumulate a burst energy storage when the PA 14 is inactive, and the output the accumulated burst energy to the PA 14 when the PA 14 is active, thereby supplying the burst power P_{burst} for the BM traffic. The burst mode converter 104 acquires the energy storage during the silence period, and outputs the acquired energy storage for the BM traffic, isolating the PA 14 from the power supply 12, preventing the communication device 1 from being shut down due to excessive current requirement. The burst mode converter 104 may be implemented by various RC combinational circuits as shown in FIGS. 2 through 4.

The processor 16 is configured to direct the digital data stream S_{D} to the transceiver 18, where the digital data stream S_{D} undergoes mixed signal and analog signal processing such as digital-to-analog conversion, up-conversion, amplification, and other analog filtering processes to form an analog data stream S_{D}′. The analog data stream S_{D}′ is subsequently fed into the PA 14 to be transmitted to a receiver (not shown) according to a transmit power. The transmit power may be assigned by a network system (not shown) containing the receiver or defined by the processor 16. The PA 14 is configured to draw power from the power circuit 10 according to the required transmit power. The transmission between the communication device 1 and the receiver may be by wired or wireless means.

Although in the embodiment, both the continuous mode converter 102 and the burst mode converter 104 can supply the power to the PA 14, those skilled in the art would recognize that the continuous mode converter 102 and the burst mode converter 104 may each be connected to a PA, dedicating for the CM and the BM communication respectively.

The communication device 1 provides powers to a PA according to a communication type, preserving communication device performance while implementing a power management into the communication device.

FIG. 2 is a block diagram of a communication device 2 according to an embodiment of the invention, adopted by the communication device 1 in FIG. 1. The power circuit 20 includes a power controller 200, a continuous mode converter 202 containing a buck converter 2020, and a burst mode converter 204 containing a super capacitor 2040. The power controller 200 is coupled to the continuous mode converter 202 and the burst mode converter 204, controlling the continuous mode converter 202 and the burst mode converter 204 respectively by first and second control signals S_{ctrl1} and S_{ctrl2}.

The power circuit 20 supplies powers to PAs and devices for various applications. Specifically, the embodiment illustrates a WCDMA PA 24a operative for WCDMA services, a first GSM PA 24b operative for first GSM services, a second GSM 24c operative for second GSM services, a TSCDMA PA 24d operative for TSCDMA services, and other power output 22 which may be a video output, audio output, or other data output. The WCDMA PA 24a requires a continuous power supply, while the first GSM PA 24b, the second GSM 24c and the TSCDMA PA 24d operate by BM communications. As a consequence, the continuous mode converter 202 is connected to the WCDMA PA 24a, while the burst mode converter 204 is connected to the first GSM PA 24b, the second GSM 24c and the TSCDMA PA 24d, when activated, providing for the required powers to the connected PA.

The power circuit 20 receives a battery current I_{bat} at a battery voltage V_{bat} from a battery (not shown), acquiring powers from the battery through a battery connector.

The power controller 200 is configured to determine the communication type based on the digital data stream SD or the communication type indication signal from the processor 16. When the communication type indicates a CM communication, the power controller 200 activates the continuous mode converter 202. When the communication type indicates a BM communication, the power controller 200 activates the burst mode converter 204.

The buck converter 2020 in the continuous mode converter 202 is a step-down DC-DC converter, converting the battery voltage V_{bat} to a step-down voltage. The output current delivered to the WCDMA PA is substantially constant, an output capacitor in the buck converter 2020 is considered being enough to maintain a constant voltage across its terminals during the communication cycle of the CM communication. The buck converter 2020 supplies a constant first PA current I_{PA1} at the step-down voltage to the WCDMA PA 24a, reducing the consumed power under the CM communication. For example, the WCDMA PA 24a may draw the first PA current I_{PA1} constant at 0.4 A for the entire CM communication cycle.

When the burst mode converter 204 is activated, the super capacitor 2040 is charged by the battery current I_{bat} to accumulate the burst energy when the connected PAs 24b, 24c and 24d remain inactive, and discharged by a capacitor current L_{cap} to supply the burst energy to the 24b, 24c or 24d when any one thereof is active. The battery current I_{bat} and equals to the accumulated current of PA currents I_{PA2}, I_{PA3} and I_{PA4}, which provide for the current requirement of the first GSM PA 24b, the second GSM 24c and the TSCDMA PA 24d respectively. For example, the first and second GSM PAs 24b, 24c may each require a 1.6 A peak current, the other power output 22 may be a baseband circuit drawing 0.8 A peak current as a fifth current I_{PA5}, rendering a 4 A peak current of the battery current I_{bat} to be withdrawn when the three circuits are concurrently in operation. The capacitance C of the super capacitor 2040 is determined by the battery current I_{bat} drawn out from the battery, an internal resistance of the battery, and an allowed voltage difference that the communication device is able to operate without causing a device shutdown. For example, when the communication device 1 has a shutdown voltage 3V, the battery supplies the battery voltage at 3.25V, the allowed voltage difference is 0.25V, the internal resistance is 0.05 ohm, and the battery current I_{bat} is 4 A, the capacitance C can be computed by Eq. (1):

0.25V=4 A*0.05+4 A*0.557 ms/C Eq. (1)

The capacitance C is worked out as 46.16 mF, or 50 mF approximately. With the capacitance C of 50 mF, the super capacitor 2040 can supply the burst energy to the BM PAs and devices when the PAs or the devices are in operation, preventing from drawing an excessive current, the voltage supplied to the communication device 1 dropping below the shutdown voltage, and the communication device 1 being shut down in the BM communication.

The power circuit 20 provides powers to PAs according to communication types, preserving communication performance while implementing a power management into a communication device.

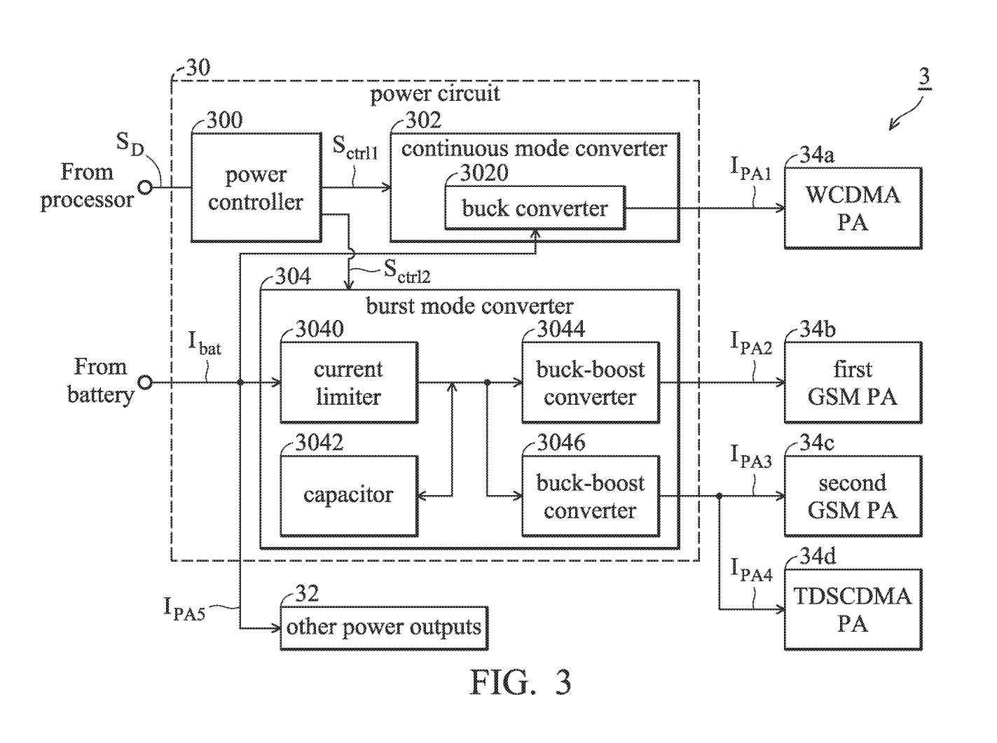

FIG. 3 is a block diagram of a communication device 3 according to another embodiment of the invention, adopted by the communication device 1 in FIG. 1. The power circuit 30 includes a power controller 300, a continuous mode converter 302 containing a buck converter 3030, and a burst mode converter 304.

Respectively, the buck converter 3030 supplies a PA current I_{PA1} to a WCDMA PA 34a, the buck-boost converter 3044 supplies a PA current I_{PA2} to a first GSM PA 24b, the buck-boost converter 3046 supplies PA currents I_{PA3} and I_{PA4} to a second GSM PA 24c and TDSCDMA PA 34d.

The circuit connection and configuration for the power circuit 30 are similar to those in the power circuit 20, reference for the similar parts can find reference in the preceding paragraphs, and will be omitted here for brevity.

The power circuit 30 is distinct form the power circuit 20 in the implementation of the burst mode converter 304, which contains a current limiter 3040, a capacitor 3042, and buck-boost converters 3044 and 3046. The power circuit 30 is configured to receive the data stream S_{D} or the communication mode indication signal from the processor, and a battery voltage V_{bat} and a battery current I_{bat} from a battery cell (power supply). The power controller 300 is configured to activate or deactivate the continuous mode converter 302 and the burst mode converter 304 by separate control signals S_{ctrl1} and S_{ctrl2}, respectively. In other words, the continuous mode converter 302 and the burst mode converter 304 are controlled independently, being turned on or turned off with no dependence of one another.

When the burst mode converter 304 is activated, the buck-boost converters 3044 and 3046 accumulate storage energies (second storage energy) for the BM communications. Because the buck-boost converters 3044 and 3046 are used to preserve considerable amounts of the storage energies (first storage energy), the capacitor 3042 is only required to hold a relatively reduced amount of storage energy.

The buck-boost converters 3044 and 3046 can store the storage energies during the supplied PA are inactive or in the silence period, and provide the storage energies to the PA when the PA is active or in BM transmissions. For example, for every 7 silent GSM slots the buck-boost converter 3044 can accumulate the story energy for the first GSM PA 34b, and in the burst GSM slot, the buck-boost converter 3044 can supply the storage energy to the first GSM PA 34b.

The buck-boost converters 3044 and 3046 can operate at one of three different working modes, namely step-up, step-down, or remain at the input battery voltage V_{bat}, isolating the input battery from the output PAs and circuits. The power controller 300 is configured to determine which mode must be used based on the battery voltage V_{bat} and desired output voltage.

If the desired output voltage is lower than the battery voltage V_{bat}, the buck-boost converters 3044 or 3046 is set to the step-down (buck) mode. As a consequence of activating the step-down mode, the burst power supplied to the BM PAs is reduced, extending the battery life of the battery cell. If the desired output voltage exceeds the battery voltage V_{bat}, the buck-boost converters 3044 or 3046 is set to the step-up mode, providing increased power performance for the PA. If the desired output voltage is substantially the same to the battery voltage V_{bat}, the buck-boost converters 3044 or 3046 is configured to the remain mode, acting as an energy buffer isolating between the battery and the PA.

The power controller 300 is configured to set the working mode and adjust the output voltages for the buck-boost converter buck-boost converters 3044 and 3046 by controlling the duty cycle of the battery current I_{bat}. The polarity of the output voltage is opposite to the battery voltage V_{bat}. A duty cycle D can vary between 0 and 1. When the duty cycle D is less than 0.5, the buck-boost converter can act as a buck converter. When the duty cycle D exceeds 0.5, the buck-boost converter serves as a boost converter. When the duty cycle D equals to 0.5, the output voltage is substantially the same as the battery voltage V_{bat}.

The size of the capacitor 3042 is determined by the energy storage capacity of the buck-boost converters 3044 and 3046. For example, when the communication device 3 has the internal resistance of 0.05ohm, the battery current I_{bat} of 4 A, and an allowed voltage difference of 2.5V due to allowance made by the storage energy in the buck-boost converters 3044 and 3046, the capacitance C required to provide the burst energy to the PA in the BM is substantially 1 mF.

The current limiter 3040 is configured to limit the battery current drawn out from the battery to a shutdown current or a predefined current of the communication device 3, so that an inadvertently battery shutdown will not occur.

The power circuit 30 provides powers to PAs according to communication types, preserving communication performance while implementing a power management into a communication device.

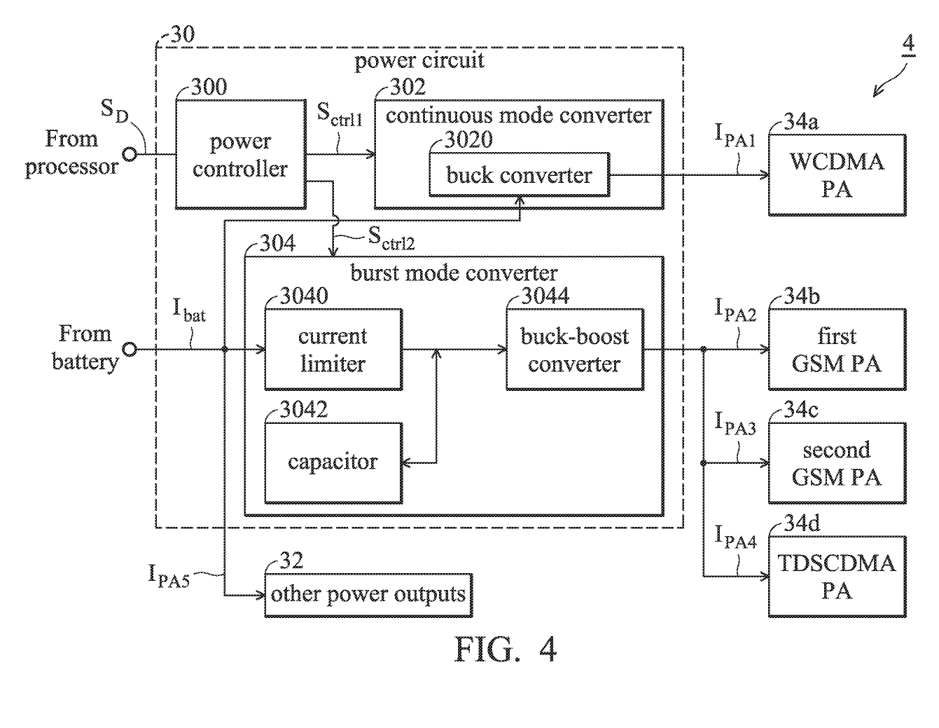

FIG. 4 is a block diagram of a communication device 4 according to another embodiment of the invention, adopted by the communication device 1 in FIG. 1.

The configurations and operations of the communication device 4 is distinct from that of the communication device 3 in that a single buck-boost converter 3044 is employed to serve for three PAs, each may demand a relatively reduced amount of burst energy during the active state. Therefore the buck-boost converter 3044 is sufficient to provide the accumulated demands of the three PAs for the burst energies.

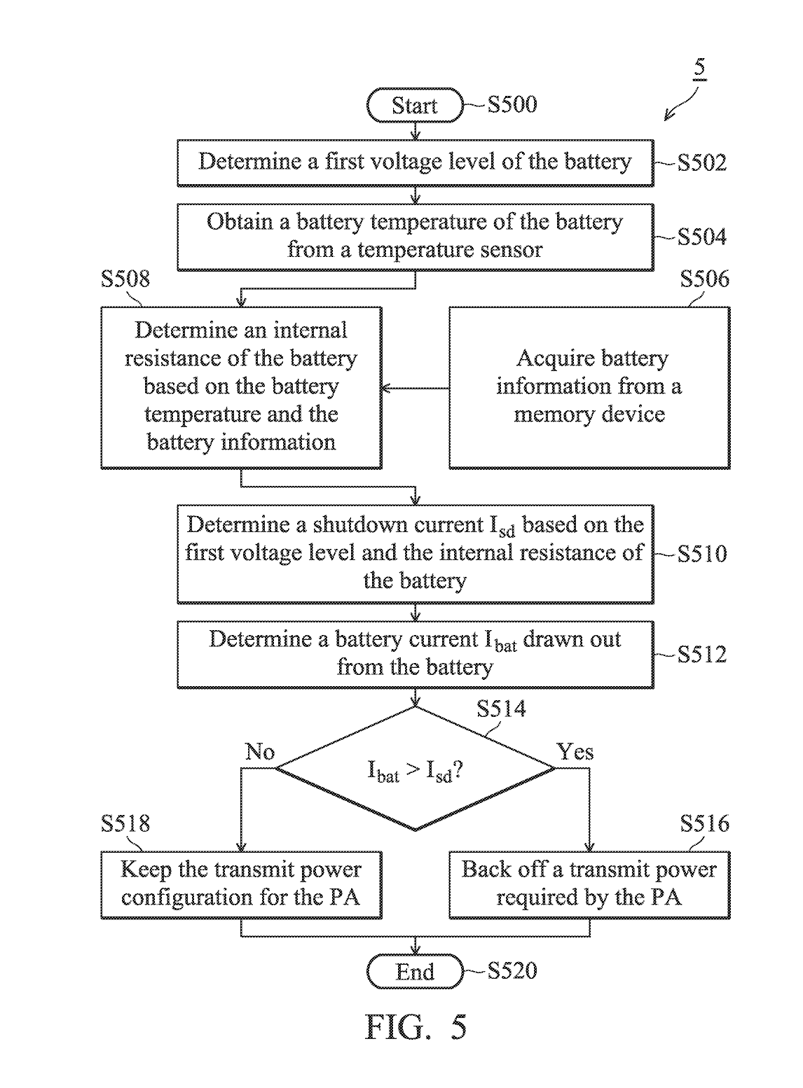

FIG. 5 is a flowchart of a power control method 5 according to an embodiment of the invention, incorporating the communication devices in FIGS. 1 through 4. For explanatory purposes, the communication device 1 will be used as an example to illustrate each step in the method 5. The power supply 12 is a limited power source such as a battery cell in a mobile phone.

Upon startup, the communication device 1 is powered on, ready for the CM or the BM transmissions (S500). The voltage level of the battery voltage varies as the battery cell discharges. The power controller 100 determines a first voltage level of the battery voltage for the battery 12 regularly or upon detecting an upcoming data transmission (S502). Concurrently or subsequently, a sensor attached to the battery detects a battery temperature of the battery, and sends the detected battery temperature to the power controller 100. The battery temperature detection may be performed periodically or just before the data transmission. In response, the power controller 100 obtains the battery temperature (S504). Combining with battery information on an internal resistance in relation to the battery temperature acquired from a memory device (not shown) (S506), the power controller 100 can determine the internal resistance of the battery based on based on the battery temperature and the battery information (S508). In some implementations, the battery information is in the form of a lookup table, the power controller 100 uses the battery temperature to search for the corresponding internal resistance from the lookup table. Subsequently, the power controller 100 determines a shutdown current I_{sd} based on the first voltage level and the internal resistance of the battery 12 (S510). The shutdown current I_{sd} is a current which, when drawn from the battery 12, will cause a voltage drop in the battery voltage that the battery voltage will fall below the shutdown voltage and the communication device 1 will be shut down accordingly. For a data communication, the power controller 100 can determine the battery current I_{bat} actually drawn out from the battery 12 (S512), which is the sum of all currents drawn by the activated PAs and circuits. The power controller 100 then proceeds with comparing the shutdown current I_{sd} and the battery current I_{bat} (S514). When the battery current I_{bat} is less than the shutdown current I_{sd}, the voltage drop caused by the internal resistance in the battery 12 will not result in the shutdown voltage, thus the power controller 100 can keep the present transmit power configuration for the PA 14 (S518). When the battery current I_{bat} exceeds or equals to the shutdown current I_{sd}, the voltage drop incurred by the internal resistance in the battery 12 will result in the shutdown voltage and lead to a device shutdown, consequently the power controller 100 is configured to back off the transmit power of the PA 14 (S516). In some embodiments, the power controller 100 may adjust the transmit power of the PA 14 by the transmit power control signal S_{TPC}, reducing the transmit power to a level which the PA 14 can draw from the power circuit 10 without causing the device shutdown.

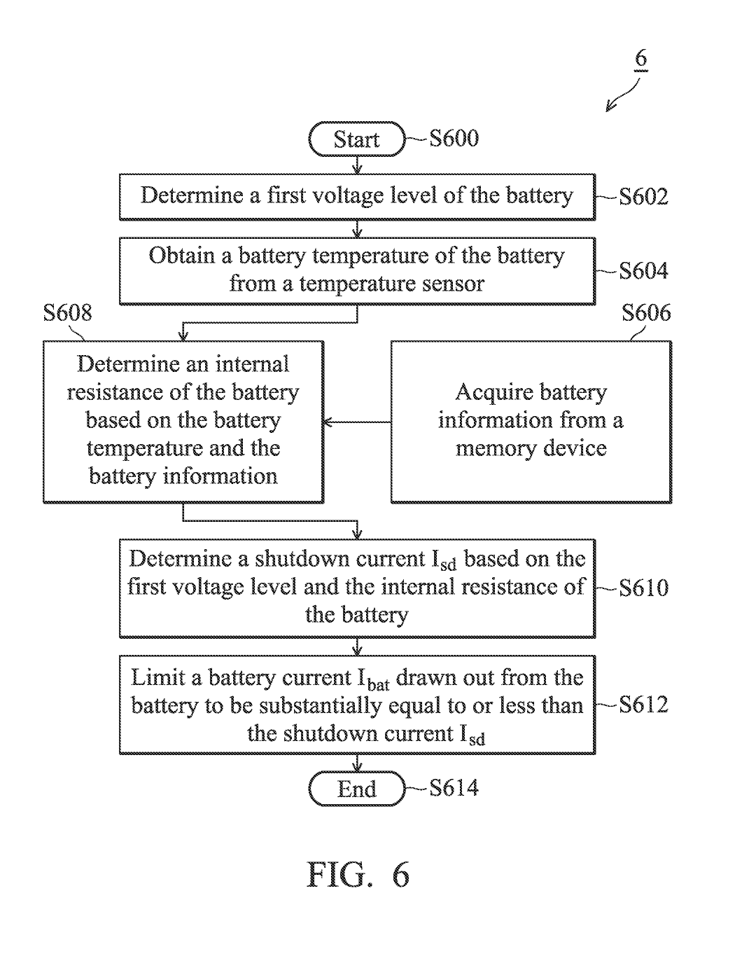

FIG. 6 is a flowchart of a power control method 6 according to another embodiment of the invention, incorporating the communication devices in FIGS. 1, 3 and 4. For explanatory purposes, the power device 30 will be used as an example to illustrate each step in the method 6.

Steps S600 through S610 are identical to Steps S500 through S510 in FIG. 5, explanation therefore can find reference in the preceding paragraphs, and will not be repeated here.

In Step S612, after the shutdown current I_{sd} is determined, the power controller 100 can limit the battery current I_{bat} to be substantially equal to or less than the shutdown current I_{sd}. Accordingly, the battery current I_{bat} is a current drawn out from the battery 12. So long as the battery current I_{bat} is limited under the shutdown current I_{sd}, the communication device 1 will not drain excessive current from the battery 12 and cause the occurrence of the shutdown voltage. The power control method 6 is thus completed and exited.

The power control methods 5 and 6 may be implemented by hardware, software, or a combination thereof. In the software implementations, the transmit power of the PA and the battery current I_{bat} may be configured by setting software register values to the desired transmit power and the shutdown current I_{sd}, respectively. The PA and current limiter are configured to operate according to the configured register values. In the hardware implementations, the transmit power of the PA and the battery current I_{bat} may be implemented by the transmit power control signal S_{TPC} and a control signal which configures the battery current I_{bat} to the shutdown current I_{sd} directly.

Although the power control methods 5 and 6 employ the shutdown current I_{sd} to control the transmit power of the PA or the battery current I_{bat}, people who skilled in the art would recognize that the power control methods 5 and 6 may also use the battery voltage received by the communication device to adjust the transmit power of the PA or the battery current I_{bat}, ensuring that the battery voltage will never fall below the shutdown voltage.

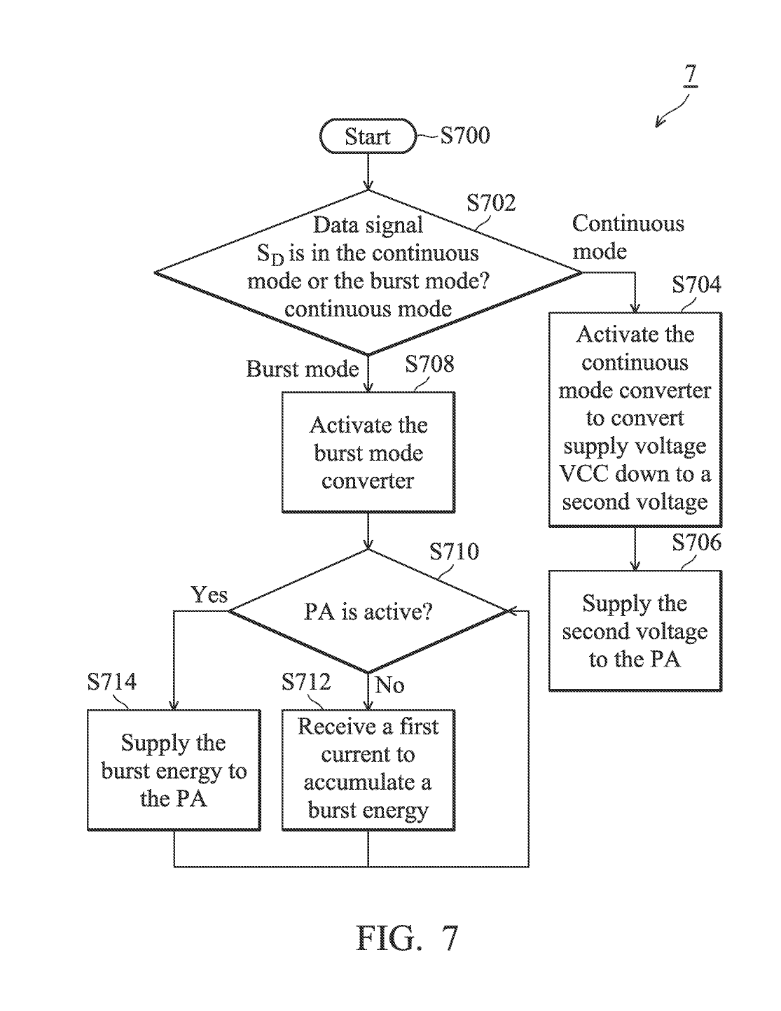

FIG. 7 is a flowchart of a power control method 7 according to another embodiment of the invention, incorporating the communication devices in FIGS. 1 through 4. For explanatory purposes, the communication device 1 will be used as an example to illustrate each step in the method 7.

Upon startup, the communication device 1 is powered on, ready for the CM or the BM transmissions (S700). When a data transmission occurs, the power controller 100 will receive the data stream signal S_{D} or the communication type indication signal, based on which the power controller 100 determines that the data stream signal S_{D} is to be transmitted in the continuous mode or the burst mode (S702). When the data signal S_{D} is to be transmitted in the burst mode, the power controller 100 activates the continuous mode converter 102, which in turn convert the supply voltage VCC down to the second voltage (S704) and supply the step-down second voltage to the PA 14 (S706), reducing the power consumption in the continuous mode. When the data signal S_{D} is to be transmitted in the continuous mode, the power controller 100 activates the burst mode converter 104, which in turn receive the supply current I_{VCC} from the power supply 12 to accumulate the burst energy when the PA 14 is inactive or in a silence period (S712) and supply the accumulated burst energy to the PA 14 when the PA is active (S714), preventing the communication device 1 from being shutdown due to drawing excessive current from the battery.

The power control methods 5 through 7 provides powers to PAs according to communication types, preserving communication performance while implementing a power management into a communication device.

As used herein, the term “determining” encompasses calculating, computing, processing, deriving, investigating, looking up (e.g., looking up in a table, a database or another data structure), ascertaining and the like. Also, “determining” may include resolving, selecting, choosing, establishing and the like.

The various illustrative logical blocks, modules and circuits described in connection with the present disclosure may be implemented or performed with a general purpose processor, a digital signal processor (DSP), an application specific integrated circuit (ASIC), a field programmable gate array signal (FPGA) or other programmable logic device, discrete gate or transistor logic, discrete hardware components or any combination thereof designed to perform the functions described herein. A general purpose processor may be a microprocessor, but in the alternative, the processor may be any commercially available processor, power controller, micropower controller or state machine.

The operations and functions of the various logical blocks, modules, and circuits described herein may be implemented in circuit hardware or embedded software codes that can be accessed and executed by a processor.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A power circuit, providing powers to a first power amplifier operating in a continuous mode or in a burst mode, connected to a power supply supplying a first voltage and a first current, comprising:
a continuous mode converter, when activated, configured to convert the first voltage down to a second voltage;
a burst mode converter, when activated, configured to receive the first current to accumulate a burst energy when the first power amplifier is inactive, and supply the burst energy to the first power amplifier when the first power amplifier is active; and
a power controller, configured to determine a first signal is to be transmitted in the continuous mode or the burst mode, when the first signal is to be transmitted in the continuous mode, activate the continuous mode converter to apply the second voltage to the first power amplifier to transmit the first signal, and when the first signal is to be transmitted in the burst mode, activate the burst mode converter to provide the burst energy to the first power amplifier to transmit the first signal.

2. The power circuit of claim 1, wherein the burst mode converter comprises:
a capacitor, charged by the first current from the power supply to accumulate a first storage energy, and configured to supply the first storage energy to the first power amplifier when the first power amplifier is active; and
a buck-boost converter, when activated, configured to receive the first current to accumulate a second storage energy when the first power amplifier is inactive, and supply the second storage energy to the first power amplifier when the first power amplifier is active.

3. The power circuit of claim 1, wherein the burst mode converter comprises a capacitor, charged by the first current from the power supply to accumulate the burst energy, when the first power amplifier is active, configured to supply the burst energy to the first power amplifier.

4. The power circuit of claim 1, wherein:
the power supply is a battery;
the power controller is further configured to determine a first voltage level of the first voltage and an internal resistance of the battery, and determine a shutdown current based on the first voltage level and the internal resistance of the battery; and
the burst mode converter comprises a current limiter, configured to limit a battery current drawn out from the battery according to the shutdown current.

5. The power circuit of claim 4, wherein:
when the battery current exceeds or equals to the shutdown current, the power controller is configured to control the current limiter to limit the battery current to be substantially equal to the shutdown current.

6. The power circuit of claim 1, wherein:
The power supply is a battery; and
the power controller is further configured to determine a first voltage level of the first voltage and an internal resistance of the battery, determine a shutdown current based on the first voltage level and the internal resistance of the battery, and adjusting a transmit power required by the first power amplifier based on the shutdown current.

7. The power circuit of claim 6, wherein:
when the battery current exceeds or equals to the shutdown current, the power controller is configured to control the first power amplifier to reduce the transmit power with an increase in a difference between the battery current and the shutdown current.

8. The power circuit of claim 1, wherein:
the power controller is further configured to reduce a duty cycle of the first current to be less than 0.5.

9. The power circuit of claim 1, wherein:
the power supply comprises a battery a temperature sensor attached to the battery, the temperature sensor is configured to sense a battery temperature of the battery; and
the power controller is further configured to receive the sensed battery temperature, and determine an internal resistance of the battery based on the sensed battery temperature.

10. The power circuit of claim 1, wherein the bust mode converter is further configured to supply the burst energy to a second power amplifier.

11. A method, adopted by a power circuit to provide powers to a first power amplifier operating in a continuous mode or in a burst mode, comprising:
determining, by a power controller, a first signal is to be transmitted by the first power amplifier in the continuous mode or the burst mode;
when the first signal is to be transmitted in the continuous mode, activating, by a power controller, a continuous mode converter;
when activated, converting, by the continuous mode converter, a first voltage down to a second voltage;
when activated, supplying, by the continuous mode converter, the second voltage to the first power amplifier;
when the first signal is to be transmitted in the burst mode, activating, by a power controller, a burst mode converter;
when activated and the first power amplifier is inactive, receiving, by a burst mode converter, a first current to accumulate a burst energy; and
when activated and the first power amplifier is active, supplying, by the burst mode converter, the burst energy to the first power amplifier.

12. The method of claim 11, wherein the burst mode converter comprises:
a capacitor, charged by the first current from the power supply to accumulate a first storage energy, and configured to supply the first storage energy to the first power amplifier when the first power amplifier is active; and
a buck-boost converter, when activated, configured to receive the first current to accumulate a second storage energy when the first power amplifier is inactive, and supply the second storage energy to the first power amplifier when the first power amplifier is active.

13. The method of claim 11, wherein the burst mode converter comprises a capacitor, charged by a first current from the power supply to accumulate the burst energy, when the first power amplifier is active, configured to supply the burst energy to the first power amplifier.

14. The method of claim 11, wherein:
The power supply is a battery;
the power controller is further configured to determine a first voltage level of the first voltage and an internal resistance of the battery, determine a shutdown current based on the first voltage level and the internal resistance of the battery; and
the burst mode converter comprises a current limiter, configured to limit a battery current drawn out from the battery according to the shutdown current.

15. The method of claim 14, wherein:
when the battery current exceeds or equals to the shutdown current, the power controller is configured to control the current limiter to limit the battery current to be substantially equal to the shutdown current.

16. The method of claim 11, wherein:
The power supply is a battery; and
the power controller is further configured to determine a first voltage level of the first voltage and an internal resistance of the battery, determine a shutdown current based on the first voltage level and the internal resistance of the battery, and adjusting a transmit power required by the first power amplifier based on the shutdown current.

17. The method of claim 16, wherein:
when the battery current exceeds or equals to the shutdown current, the power controller is configured to control the first power amplifier to reduce the transmit power with an increase in a difference between the battery current and the shutdown current.

18. The method of claim 11, wherein:
the power controller is further configured to reduce a duty cycle of the first current to be less than 0.5.

19. The method of claim 11, wherein:
the power supply comprises a battery a temperature sensor attached to the battery, the temperature sensor is configured to sense a battery temperature of the battery; and
the power controller is further configured to receive the sensed battery temperature, and determine an internal resistance of the battery based on the sensed battery temperature.

20. The method of claim 11, wherein the bust mode converter is further configured to supply the burst energy to a second power amplifier.
